(19) United States
(12) Patent Application Publication
(10) Pub. No.: US 2025/0149357 A1
(43) Pub. Date: May 8, 2025

(54) APPARATUS FOR PROCESSING A WAFER

(71) Applicant: SAMSUNG ELECTRONICS CO., LTD., Suwon-si (KR)

(72) Inventors: Hyuntae Kim, Suwon-si (KR); Kyungyeol Kim, Suwon-si (KR); Jwahyeon Kim, Suwon-si (KR); Taesung Kim, Suwon-si (KR); Byunghyuck Ahn, Suwon-si (KR)

(21) Appl. No.: 18/640,980

(22) Filed: Apr. 19, 2024

(30) Foreign Application Priority Data
Nov. 2, 2023 (KR) 10-2023-0149995

(51) Int. Cl. H01L 21/67; B24B 41/00; H01L 21/677; H01L 21/687

(52) U.S. Cl. CPC H01L 21/67196; B24B 41/005; H01L 21/67132; H01L 21/67703; H01L 21/68707

(57) ABSTRACT

An example apparatus for processing a wafer includes a grinder, a mounter, and a dock. The grinder is configured to grind a backside of the wafer. The mounter is configured to attach a ring to the wafer. The mounter is configured to remove a protection film from the wafer. The dock configured to dock the mounter with the grinder.

### CROSS-REFERENCE TO RELATED APPLICATION

This application claims priority under 35 USC § 119 to Korean Patent Application No. 10-2023-0149995, filed on Nov. 2, 2023 in the Korean Intellectual Property Office (KIPO), the disclosure of which is incorporated herein by reference in its entirety.

### BACKGROUND

Generally, in order to reduce a thickness of a wafer, a backside of the wafer may be removed using a grinder. Before a grinding process, a protection film configured to protect a circuit of the wafer may be attached to the wafer. After the grinding process, in order to handle the wafer having a thin thickness, a ring may be attached to the wafer. Further, the protection film may then be removed from the wafer. The attachment of the ring and the removal of the protection film may be performed by a mounter.

A repair space may be formed between the grinder and the mounter. That is, the grinder may be spaced apart from the mounter by the repair space. Thus, the grinder and the mounter may occupy a large space.

### SUMMARY

The present disclosure relates to apparatuses, including an apparatus for processing a wafer capable of reducing an occupying area.

In some implementations, an apparatus for processing a wafer includes a grinder, a mounter and a dock. The grinder may be configured to grind a backside of the wafer. The mounter may be configured to attach a ring to the wafer. The mounter may be configured to remove a protection film from the wafer. The dock may be configured to selectively dock the mounter with the grinder.

In some implementations, an apparatus for processing a wafer includes a grinder, a mounter and a dock. The grinder may be configured to a backside of the wafer. The mounter may be configured to attach a ring to the wafer. The mounter may be configured to remove a protection film from the wafer. The dock may be configured to selectively dock the mounter with the grinder. The dock may include a rail, an actuator, a locking cylinder, a locking bracket and a plurality of air casters. The rail may be extended from an upper surface of the grinder. The rail may be connected to an upper surface of the mounter. The locking cylinder may be arranged at the grinder. The locking bracket may be arranged at the mounter. The locking bracket may be locked with the locking cylinder. The plurality of the air casters may be arranged on a lower surface of the mounter.

In some implementations, the mounter may be docked with the grinder by the dock so that a space may not be formed between the grinder and the mounter. When only a repair of the grinder and/or the mounter may be required, the mounter may be separated from the grinder by the dock to form the repair space between the grinder and the mounter. Thus, the grinder and the mounter may have a small occupying area.

### BRIEF DESCRIPTION OF THE DRAWINGS

Implementations will be more clearly understood from the following detailed description taken in conjunction with the accompanying drawings. FIGS. 1 to 11 represent non-limiting, example implementations as described herein.

FIG. 1 is a perspective view illustrating an example of an apparatus for processing a wafer.

FIGS. 2 and 3 are example plan views illustrating the apparatus in FIG. 1.

FIG. 4 is a side view illustrating an example of a mounter of the apparatus in FIG. 1.

FIG. 5 is a perspective view illustrating an example of a locking cylinder in a dock of the apparatus in FIG. 1.

FIG. 6 is a perspective view illustrating an example of a locking bracket in a dock of the apparatus in FIG. 1.

FIG. 7 is an example perspective view illustrating the locking cylinder in FIG. 5 locked with the locking bracket in FIG. 6.

FIG. 8 is a perspective view illustrating an example of an air caster in a dock of the apparatus in FIG. 1.

FIG. 9 is a cross-sectional view illustrating an example of a mounter supported by the air caster in FIG. 8.

FIGS. 10 and 11 are plan views illustrating an example of an apparatus for processing a wafer.

### DETAILED DESCRIPTION

Hereinafter, example implementations will be explained in detail with reference to the accompanying drawings.

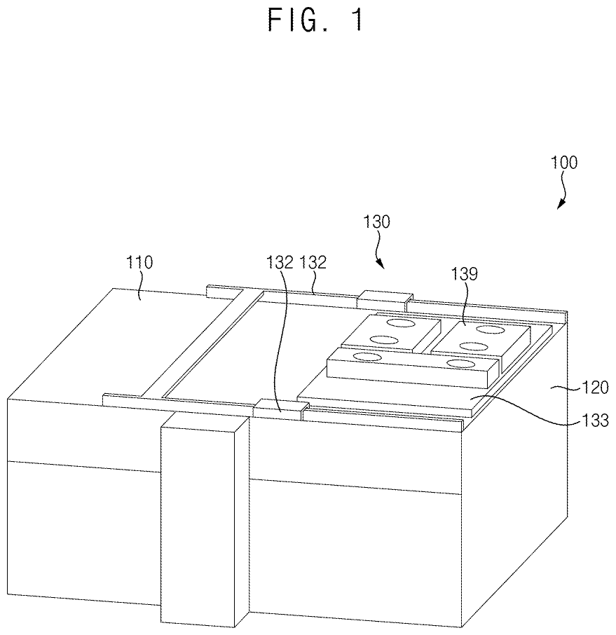

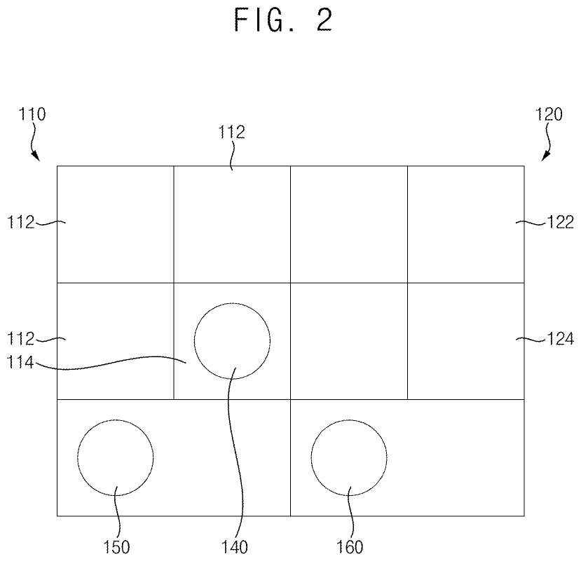

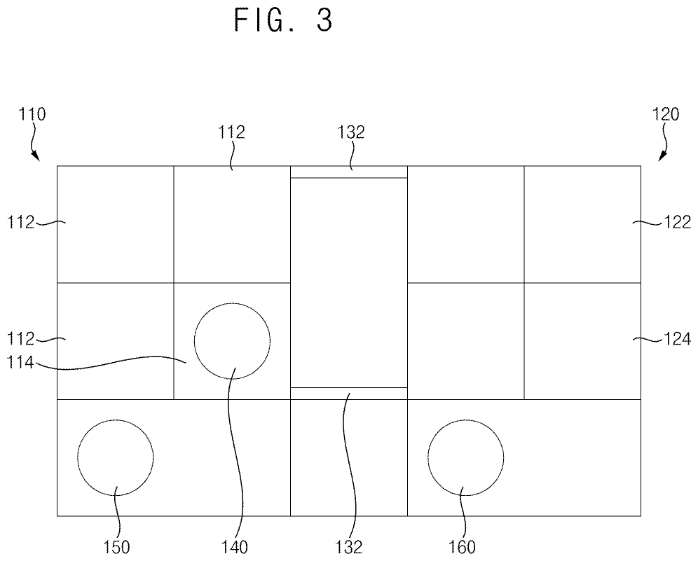

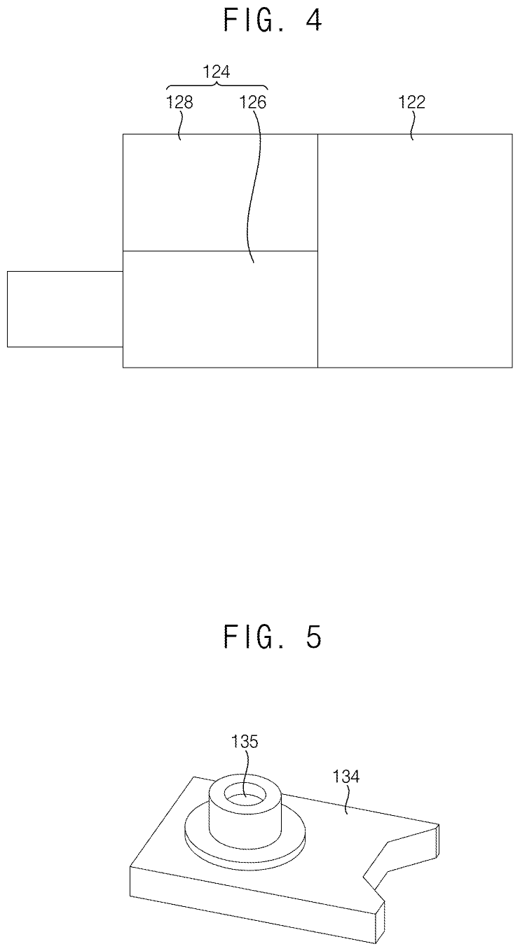

FIG. 1 is a perspective view illustrating an example of an apparatus for processing a wafer, FIGS. 2 and 3 are example plan views illustrating the apparatus in FIG. 1, and FIG. 4 is a side view illustrating an example of a mounter of the apparatus in FIG. 1.

Referring to FIGS. 1 to 4, an apparatus 100 for processing a wafer may include a grinder 110, a mounter 120, a loading robot 150, a transfer robot 140, an unloading robot 160 and a dock 130.

The grinder 110 may grind a backside of the wafer to reduce a thickness of the wafer. Before the grinding process, in order to protect a circuit of the wafer, a protection film may be attached to a front side of the wafer. The loading robot 150 may load the wafer into the grinder 110.

In some implementations, the grinder 110 may include a plurality of grinding chambers 112. A grinder configured to grind the backside of the wafer may be arranged in each of the grinding chambers 112. The grinding chambers 112 may be four chambers arranged in a rectangular shape, but not limited thereto. One right chamber among the grinding chambers 112 may correspond to a transfer chamber 114 configured to transfer the wafer.

The mounter 120 may be arranged adjacent to the grinder 110. In some implementations, the mounter 120 may be positioned right the grinder 110, but not limited thereto. Particularly, before processing the wafer, facing sidewalls of the grinder 110 and the mounter 120 may closely make contact with each other. That is, a right sidewall of the grinder 110 may closely make contact with a left sidewall of the mounter 120. Thus, a space may not be formed between the right sidewall of the grinder 110 and the left sidewall of the mounter 120. As a result, the grinder 110 and the mounter 120 may have a small occupying area. The unloading robot 150 may unload the wafer processed by the mounter 120 from the mounter 120.

The mounter 120 may include an attaching chamber 122 and a peeling chamber 124. A process for attaching a ring to the wafer having a thin thickness by the grinding process may be performed in the attaching chamber 122. A process for removing the protection film from the wafer may be performed in the peeling chamber 124. The attaching process may be relatively performed in a short time. In contrast, the peeling process may be relatively performed in a long time.

In order to increase a speed for processing the wafer, the peeling chamber 124 may include a plurality of stacked chambers. In some implementations, the peeling chamber 124 may include a lower peeling chamber 126 and an upper peeling chamber 128 stacked on the lower peeling chamber 126, but not limited thereto.

The transfer robot 140 may be arranged in the transfer chamber 114. The transfer robot 140 may transfer the wafer, which may be processed by the grinder 110, to the mounter 120. Thus, an entrance for transferring the wafer may be formed through the right sidewall of the grinder 110 and the left sidewall of the mounter 120. Further, a shutter configured to open and close the entrance may be arranged at the entrance.

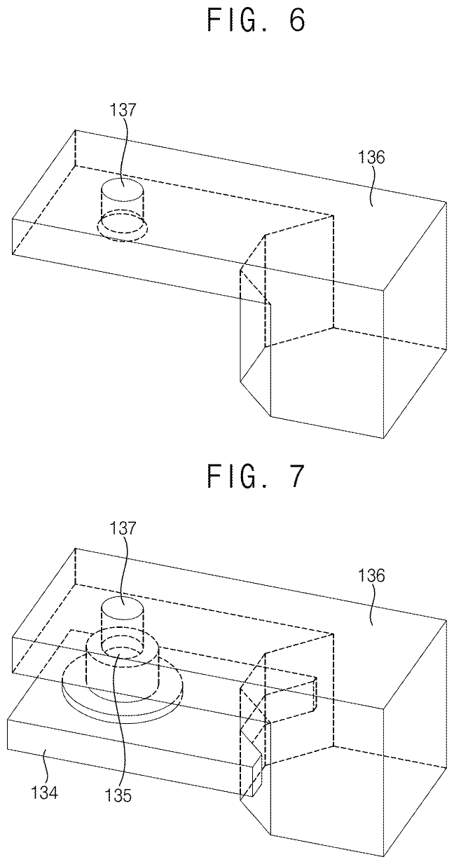

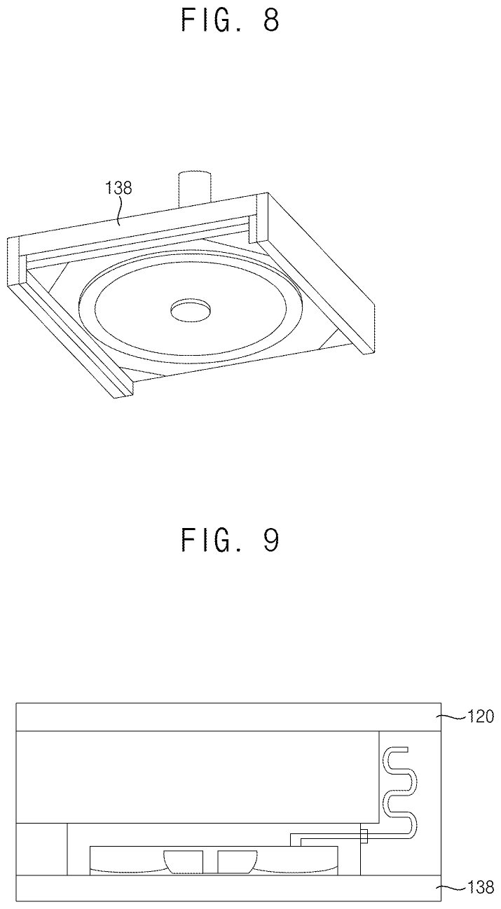

FIG. 5 is a perspective view illustrating an example of a locking cylinder in a dock of the apparatus in FIG. 1, FIG. 6 is a perspective view illustrating an example of a locking bracket in a dock of the apparatus in FIG. 1, FIG. 7 is an example perspective view illustrating the locking cylinder in FIG. 5 locked with the locking bracket in FIG. 6, FIG. 8 is a perspective view illustrating an example of an air caster in a dock of the apparatus in FIG. 1, and FIG. 9 is a cross-sectional view illustrating an example of a mounter supported by the air caster in FIG. 8.

Referring to FIGS. 1 to 5 and 9, the dock 130 may be configured to selectively dock the mounter 120 with the grinder 110. That is, in the process for processing the wafer, the dock 130 can dock the mounter 120 with the grinder 110 to cause the left sidewall of the mounter 120 to contact the right sidewall of the grinder 110, thereby prohibiting a space from being created between the grinder 110 and the mounter 120. In a repair process, the dock 130 can separate the mounter 120 from the grinder 110, thereby creating a space between the right sidewall of the grinder 110 and the left sidewall of the mounter 120.

The dock 130 may include a rail 132, a transfer block 133, an actuator 139, a locking cylinder 134, a locking bracket 136 and a plurality of air casters 138.

The rail 132 may be extended from the grinder 110 to the mounter 120. In some implementations, the rail 132 may be extended from an upper surface of the grinder 110. Further, the rail 132 may include a pair of rails arranged on both edge portions of the upper surface of the grinder 110, but not limited thereto. For example, the rail 132 may include at least three rails.

The transfer block 133 may be installed at the upper surface of the mounter 120. The transfer block 133 may be movably connected to the rail 132. Particularly, both ends of the transfer block 133 may be movably connected to the rail 132. For example, rollers may be provided to the both ends of the transfer block 133. The rollers may be rotatably connected to the rail 132.

The mounter 120 may be movably connected with the rail 132 via the transfer block 133. Thus, when the transfer block 133 may be moved on the rail 132, the mounter 120 may be moved forwardly toward or backwardly from the grinder 110. A sensor may detect a position of the mounter 120 on the rail 132.

The actuator 139 may provide the transfer block 133 with a force to move the mounter 120 on the rail 132. The actuator 139 may include a motor, a cylinder, etc., but not limited thereto. An operation of the actuator 139 may be controlled by the position of the mounter 120 detected by the sensor.

The locking cylinder 134 may be arranged at the grinder 110. The locking cylinder 134 may include a locking pin 135. The locking pin 135 may be moved upwardly or downwardly by the locking cylinder 134.

The locking bracket 136 may be arranged at the mounter 120. The locking bracket 136 may include a locking hole 137. The locking pin 135 may be selectively inserted into the locking hole 137. That is, when the locking pin 135 may be inserted into the locking hole 137, the locking cylinder 134 may be locked with the locking bracket 136. In contrast, when the locking pin 135 may be released from the locking hole 137, the locking cylinder 134 may be separated from the locking bracket 136.

The air casters 138 may be arranged on a lower surface of the mounter 120. The air casters 138 may be moved on a floor in every direction. Further, the air casters 138 may be configured to float the mounter 120 from the floor using air. Thus, an impact, which may be applied to the mounter 120 moved on the rail 132, may be decreased. In some implementations, the air casters 138 may be positioned at corners on the lower surface of the mounter 120, but not limited thereto.

In order to dock the mounter 120 with the grinder 110, the mounter 120 may be forwardly moved toward the grinder 110 on the rail 132 by the actuator 139. When the left sidewall of the mounter 120 may make contact with the right sidewall of the grinder 110, the locking cylinder 134 may be inserted into the locking bracket 136. The locking cylinder 134 may upwardly move the locking pin 135 so that the locking pin 135 may be inserted into the locking hole 137. Thus, the locking cylinder 134 may be locked with the locking bracket 136. As a result, the mounter 120 may be docked with the grinder 110.

In order to separate the mounter 120 from the grinder 110, the locking cylinder 134 may downwardly move the locking pin 135 so that the locking pin 135 may be released from the locking hole 137. Thus, the locking cylinder 134 may be separated from the locking bracket 136. As a result, the mounter 120 may be separated from the grinder 110. The mounter 120 may be backwardly moved from the grinder 110 on the rail 132 by the actuator 139. Therefore, the repair space may be formed between the grinder 110 and the mounter 120.

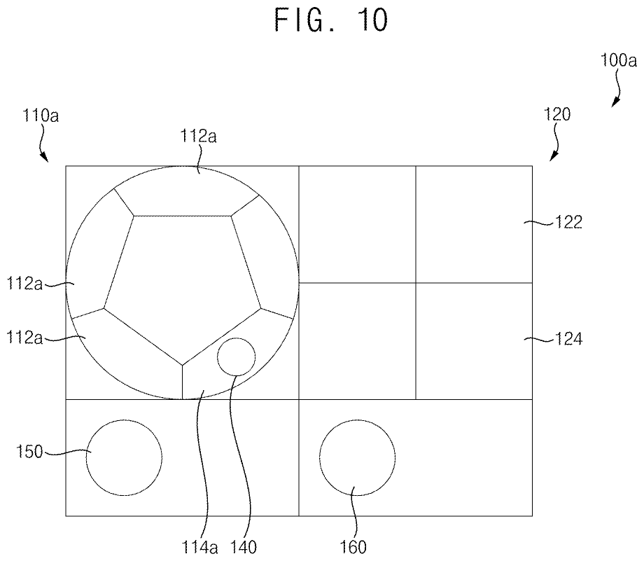

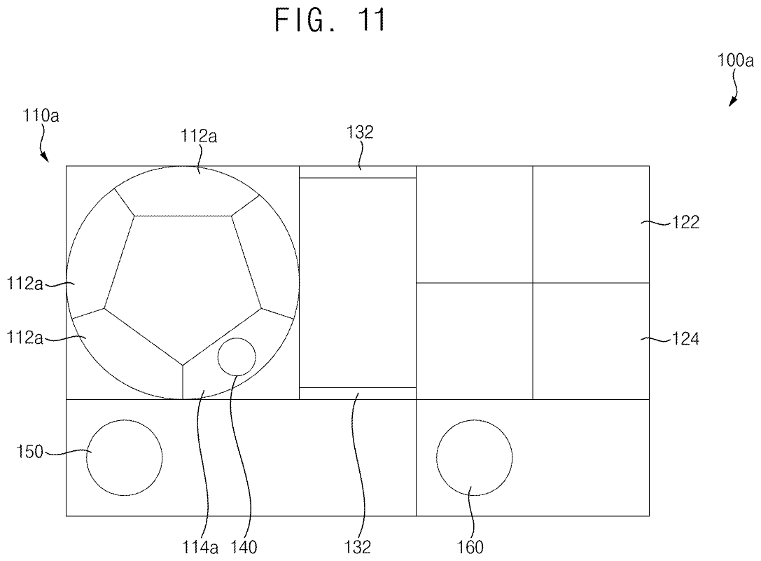

FIGS. 10 and 11 are plan views illustrating an example of an apparatus for processing a wafer.

An apparatus 100a for processing a wafer may include elements substantially the same as those of the apparatus 100 in FIGS. 2 and 3 except for a grinder. Thus, the same reference numerals may refer to the same elements and any further illustrations with respect to the same elements may be omitted herein for brevity.

Referring to FIGS. 10 and 11, a grinder 110a may include a plurality of grinding chambers 112a arranged in a radial direction. In some implementations, the grinding chambers 112a may be five, but not limited thereto.

Further, a chamber, which may be adjacent to a right sidewall of the grinder 110a, in the grinding chambers 112a may correspond to a transfer chamber 114a.

In some implementations, the mounter may be docked with the grinder by the dock so that a space may not be formed between the grinder and the mounter. When only a repair of the grinder and/or the mounter may be required, the mounter may be separated from the grinder by the dock to form the repair space between the grinder and the mounter. Thus, the grinder and the mounter may have a small occupying area.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in the example implementations without droplet departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

What is claimed is:

1. An apparatus for processing a wafer, the apparatus comprising:
a grinder configured to grind a backside of the wafer;
a mounter configured to attach a ring to the wafer, and remove a protection film from the wafer; and
a dock configured to dock the mounter with the grinder.

2. The apparatus of claim 1, wherein the dock comprises:
a rail configured to extend from the grinder;
a transfer block configured to be connected with the rail and move on the rail, the transfer block being configured to be fixed to the mounter; and
an actuator configured to move the transfer block on the rail.

3. The apparatus of claim 2, wherein the rail is configured to be connected with an upper surface of the grinder and an upper surface of the mounter.

4. The apparatus of claim 2, wherein the dock comprises:
a locking cylinder configured to be positioned at the grinder; and
a locking bracket configured to be positioned at the mounter and locked with the locking cylinder.

5. The apparatus of claim 2, wherein the dock comprises a plurality of air casters configured to be positioned on a lower surface of the mounter.

6. The apparatus of claim 1, comprising a transfer robot configured to transfer the wafer from the grinder to the mounter.

7. The apparatus of claim 1, wherein the grinder comprises a plurality of grinding chambers.

8. The apparatus of claim 7, wherein the plurality of the grinding chambers are positioned in a rectangular shape.

9. The apparatus of claim 7, wherein the plurality of the grinding chambers are positioned in a radial direction.

10. The apparatus of claim 1, wherein the mounter comprises:
an attaching chamber configured to attach the ring to the wafer; and
at least one peeling chamber configured to remove the protection film from the wafer.

11. The apparatus of claim 10, wherein the at least one peeling chamber comprises a plurality of stacked chambers.

12. The apparatus of claim 1, comprising a loading robot configured to load the wafer into the grinder.

13. The apparatus of claim 1, comprising an unloading robot configured to unload the wafer from the mounter.

14. An apparatus for processing a wafer, the apparatus comprising:
a grinder configured to grind a backside of the wafer;
a mounter configured to attach a ring to the wafer, and remove a protection film from the wafer;
a transfer robot configured to transfer the wafer from the grinder to the mounter; and
a dock configured to dock the mounter with the grinder,
wherein the dock comprises:
a rail configured to extend from the grinder;
a transfer block configured to be connected with the rail and move on the rail, the transfer block being configured to be fixed to the mounter;
an actuator configured to move the transfer block on the rail;
a locking cylinder configured to be positioned at the grinder;
a locking bracket configured to be positioned at the mounter and locked with the locking cylinder; and
a plurality of air casters configured to be positioned on a lower surface of the mounter.

15. The apparatus of claim 14, wherein the grinder comprises a plurality of grinding chambers.

16. The apparatus of claim 15, wherein the plurality of the grinding chambers are positioned in a rectangular shape.

17. The apparatus of claim 15, wherein the plurality of the grinding chambers are positioned in a radial direction.

18. The apparatus of claim 14, wherein the mounter comprises:
an attaching chamber configured to attach the ring to the wafer; and
at least one peeling chamber configured to remove the protection film from the wafer.

19. The apparatus of claim 18, wherein the at least one peeling chamber comprises a plurality of stacked chambers.

20. The apparatus of claim 14, comprising:
a loading robot configured to load the wafer into the grinder; and
an unloading robot configured to unload the wafer from the mounter.
